(19) United States
(12) Patent Application Publication
(10) Pub. No.: US 2014/0055214 A1
(43) Pub. Date: Feb. 27, 2014

(54) MULTI-MODE BANDPASS FILTER

(71) Applicant: QUALCOMM INCORPORATED, San Diego, CA (US)

(72) Inventors: Sanghoon Joo, Sunnyvale, CA (US); Chi Shun Lo, San Diego, CA (US); Chengjie Zuo, Santee, CA (US); Changhan Hobie Yun, San Diego, CA (US); Jonghae Kim, San Diego, CA (US)

(73) Assignee: QUALCOMM INCORPORATED, San Diego, CA (US)

(21) Appl. No.: 13/765,669

(22) Filed: Feb. 12, 2013

Related U.S. Application Data
(60) Provisional application No. 61/612,888, filed on Mar. 19, 2012.

(51) Int. Cl. H03H 9/70; H03H 9/54

(52) U.S. Cl. CPC H03H 9/54
USPC 333/189; 333/133

(57) ABSTRACT

A multi-mode bandpass filter is described. The bandpass filter includes a first multi-directional vibrating microelectromechanical systems resonator. The bandpass filter also includes a second multi-directional vibrating microelectromechanical systems resonator. The first multi-directional vibrating microelectromechanical systems resonator is in a parallel configuration. The second multi-directional vibrating microelectromechanical systems resonator is in a series configuration.

### CLAIM OF PRIORITY UNDER 35 U.S.C. 119

The present application for patent claims priority to Provisional Application No. 61/612,888, entitled “Dual(multi)-mode bandpass filter using MEMS resonators” filed Mar. 19, 2012, and assigned to the assignee hereof and hereby expressly incorporated by reference herein.

### TECHNICAL FIELD

The present disclosure relates generally to wireless communication systems. More specifically, the present disclosure relates to systems and methods generating a multi-mode bandpass filter.

### BACKGROUND

Electronic devices (cellular telephones, wireless modems, computers, digital music players, Global Positioning System units, Personal Digital Assistants, gaming devices, etc.) have become a part of everyday life. Small computing devices are now placed in everything from automobiles to housing locks. The complexity of electronic devices has increased dramatically in the last few years. For example, many electronic devices have one or more processors that help control the device, as well as a number of digital circuits to support the processor and other parts of the device.

Various electronic circuit components can be implemented at the electromechanical systems level, such as resonators. The increased complexity has led to integrated circuit real estate becoming very expensive. Many circuit components are utilized in processing a signal, including filters. Filters may be designed to pass a specific frequency. In applications where multiple signals are being processed, many different filters may be implemented in an electronic device. Benefits may be realized by improved systems and methods for generating a multi-mode bandpass filter.

### SUMMARY

A multi-mode bandpass filter is described. The multi-mode bandpass filter includes a first multi-directional vibrating microelectromechanical systems (MEMS) resonator. The multi-mode bandpass filter also includes a second multi-directional vibrating microelectromechanical systems (MEMS) resonator. The first multi-directional vibrating microelectromechanical systems (MEMS) resonator is in a parallel configuration. The second multi-directional vibrating microelectromechanical systems (MEMS) resonator is in a series configuration.

Each of the multi-directional vibrating microelectromechanical systems (MEMS) resonators may include a piezoelectric material. Each of the multi-directional vibrating microelectromechanical systems (MEMS) resonators may also include a first electrode on a first surface of the piezoelectric material. Each of the multi-directional vibrating microelectromechanical systems (MEMS) resonators may also include a second electrode on a second surface of the piezoelectric material. The first electrode may be an input electrode. The second electrode may be an output electrode. An electric field applied across the first electrode and the second electrode may induce mechanical deformation in at least one plane of the piezoelectric material.

The piezoelectric material may include one of aluminum nitride, lithium niobate, lithium tantalate, lead zirconate titanate, zinc oxide and quartz. Each of the multi-directional vibrating microelectromechanical systems (MEMS) resonators may have a first transverse piezoelectric coefficient, a second transverse piezoelectric coefficient and a longitudinal piezoelectric coefficient for the piezoelectric material. Each first transverse piezoelectric coefficient, second transverse piezoelectric coefficient and longitudinal piezoelectric coefficient of each multi-directional vibrating microelectromechanical systems (MEMS) resonator may be associated with a resonant frequency. Each of the multi-directional vibrating microelectromechanical systems (MEMS) resonators may resonate at three resonant frequencies.

Each multi-directional vibrating microelectromechanical systems (MEMS) resonator may have a resonator width, a resonator length and a resonator thickness. Each resonator width, resonator length and resonator thickness of each multi-directional vibrating microelectromechanical systems (MEMS) resonator may be associated with a resonant frequency.

Each multi-directional vibrating microelectromechanical systems (MEMS) resonator may have a resonator width and a corresponding first transverse piezoelectric coefficient, a resonator length and a corresponding second transverse piezoelectric coefficient and a resonator thickness and a corresponding longitudinal piezoelectric coefficient. Each resonator width and corresponding first transverse piezoelectric coefficient, resonator length and corresponding second transverse piezoelectric coefficient and resonator thickness and corresponding longitudinal piezoelectric coefficient of each multi-directional vibrating microelectromechanical systems (MEMS) resonator may be associated with a resonant frequency.

The first multi-directional vibrating microelectromechanical systems (MEMS) resonator may include a first resonator width, a first resonator thickness and a first resonator length. The second multi-directional vibrating microelectromechanical systems (MEMS) resonator may include a second resonator width, a second resonator thickness and a second resonator length. Each of the first resonator width, the first resonator thickness, the first resonator length, the second resonator width, the second resonator thickness and the second resonator length may be associated with a resonant frequency. Each of the resonant frequencies associated with the first resonator width, the first resonator thickness and the first resonator length may be offset from each of the resonant frequencies associated with the second resonator width, the second resonator thickness and the second resonator length. A frequency range of the offset for each of the resonant frequencies may correspond to a bandwidth of frequencies passed by the multi-mode bandpass filter.

Each of the resonant frequencies associated with the first resonator width, the first resonator thickness and the first resonator length may be aligned with each of the resonant frequencies associated with the second resonator width, the second resonator thickness and the second resonator length. A bandwidth of frequencies passed by the multi-mode bandpass filter may correspond to a first electromechanical coupling of the first multi-directional vibrating microelectromechanical systems (MEMS) resonator and a second electromechanical coupling of the second multi-directional vibrating microelectromechanical systems (MEMS) resonator.

A method for generating a multi-mode bandpass filter is also described. The method includes generating a parallel multi-directional vibrating microelectromechanical systems (MEMS) resonator. The method also includes generating a series multi-directional vibrating microelectromechanical systems (MEMS) resonator. The method also includes generating a multi-mode bandpass filter using the parallel multi-directional vibrating microelectromechanical systems (MEMS) resonator and the series multi-directional vibrating microelectromechanical systems (MEMS) resonator.

An apparatus configured for generating a multi-mode bandpass filter is also described. The apparatus includes a means for generating a parallel multi-directional vibrating microelectromechanical systems (MEMS) resonator. The apparatus also includes a means for generating a series multi-directional vibrating microelectromechanical systems (MEMS) resonator. The apparatus also includes a means generating a multi-mode bandpass filter using the parallel multi-directional vibrating microelectromechanical systems (MEMS) resonator and the series multi-directional vibrating microelectromechanical systems (MEMS) resonator.

A computer-program product for generating a multi-mode bandpass filter is also described. The computer-program product includes a non-transitory computer-readable medium having instructions thereon. The instructions include code for causing an apparatus to generate a parallel multi-directional vibrating microelectromechanical systems (MEMS) resonator. The instructions also include code for causing the apparatus to generate a series multi-directional vibrating microelectromechanical systems (MEMS) resonator. The instructions also include code for causing the apparatus to generate a multi-mode bandpass filter using the parallel multi-directional vibrating microelectromechanical systems (MEMS) resonator and the series multi-directional vibrating microelectromechanical systems (MEMS) resonator.

### BRIEF DESCRIPTION OF THE DRAWINGS

FIG. 1 is a block diagram illustrating a multi-mode bandpass filter;

FIG. 2 is a block diagram illustrating a perspective view of a multi-directional vibrating microelectromechanical systems (MEMS) resonator;

FIG. 3 is a circuit diagram illustrating one example of a multi-mode bandpass filter;

FIG. 4 illustrates graphs of the frequency responses of a parallel multi-directional vibrating microelectromechanical systems (MEMS) resonator and a series multi-directional vibrating microelectromechanical systems (MEMS) resonator;

FIG. 5 illustrates a graph of frequency responses for two multi-directional vibrating microelectromechanical systems (MEMS) resonators;

FIG. 6 illustrates a graph of a multi-mode bandpass filter response;

FIG. 7 is a flow diagram of a method for generating a multi-mode bandpass filter;

FIG. 8 is a diagram illustrating a perspective view of one configuration of a multi-band microelectromechanical systems (MEMS) filter;

FIG. 9 is a diagram illustrating a perspective view of another configuration of a multi-band microelectromechanical systems (MEMS) filter;

FIG. 10 is a diagram illustrating a perspective view of yet another configuration of a multi-band microelectromechanical systems (MEMS) filter;

FIG. 11 is a diagram illustrating a perspective view of another configuration of a multi-band microelectromechanical systems (MEMS) filter;

FIG. 12 is a diagram illustrating a perspective view of yet another configuration of a multi-band microelectromechanical systems (MEMS) filter;

FIG. 13 is a diagram illustrating a perspective view of another configuration of a multi-band microelectromechanical systems (MEMS) filter; and

FIG. 14 illustrates certain components that may be included within an electronic device/wireless device.

### DETAILED DESCRIPTION

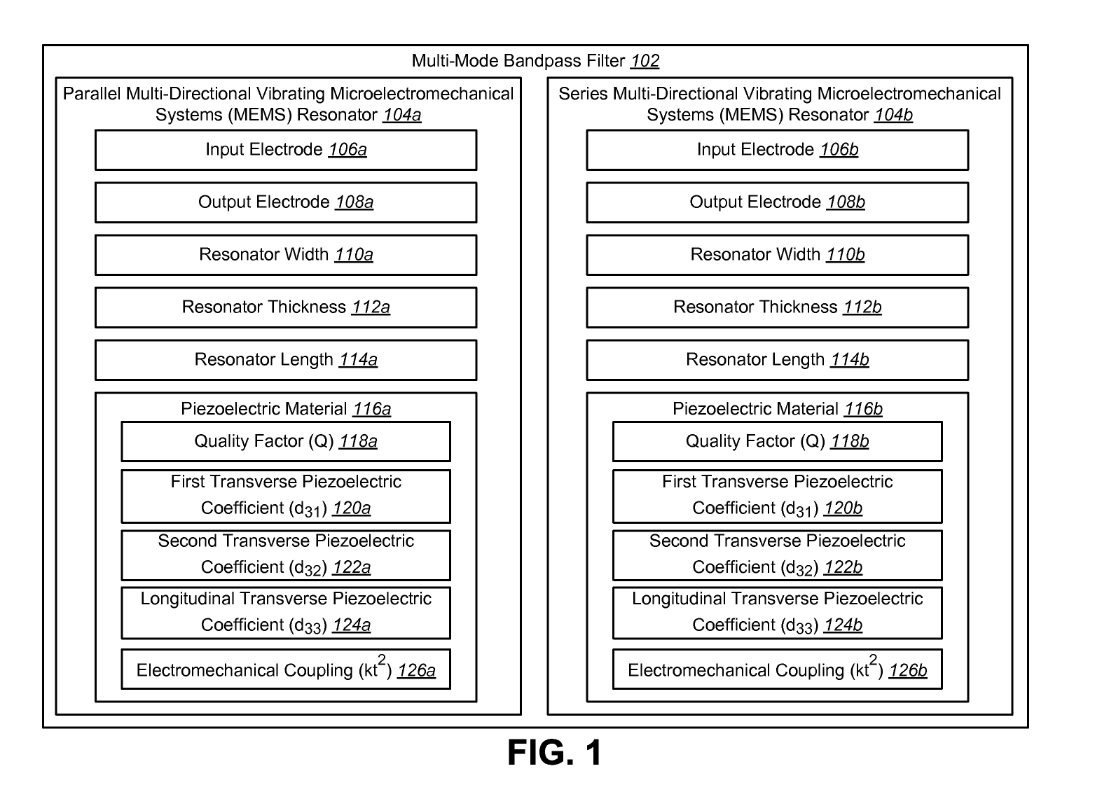

FIG. 1 is a block diagram illustrating a multi-mode bandpass filter 102. Multiple multi-directional vibrating microelectromechanical systems (MEMS) resonators 104a-b may be utilized to build a radio frequency (RF) filter such as the multi-mode bandpass filter 102. The multi-mode bandpass filter 102 may include a parallel multi-directional vibrating microelectromechanical systems (MEMS) resonator 104a. The multi-mode bandpass filter 102 may also include a series multi-directional vibrating microelectromechanical systems (MEMS) resonator 104b.

In general, a multi-directional vibrating microelectromechanical systems (MEMS) resonator 104 structure may be suspended in a cavity that includes specially designed tethers coupling the multi-directional vibrating microelectromechanical systems (MEMS) resonator 104 structure to a supporting structure. These tethers may be fabricated in the layer stack of the multi-directional vibrating microelectromechanical systems (MEMS) resonator 104 structure. The multi-directional vibrating microelectromechanical systems (MEMS) resonator 104 structure may be acoustically isolated from the surrounding structural support and other components by virtue of a cavity.

Many different kinds of electronic devices may benefit from multi-directional vibrating microelectromechanical systems (MEMS) resonators 104 used to build a multi-mode bandpass filter 102. Different kinds of such devices include, but are not limited to, cellular telephones, wireless modems, computers, digital music players, Global Positioning System units, Personal Digital Assistants, gaming devices, etc. One group of devices includes those that may be used with wireless communication systems. As used herein, the term “wireless communication device” refers to an electronic device that may be used for voice and/or data communication over a wireless communication network. Examples of wireless communication devices include cellular phones, handheld wireless devices, wireless modems, laptop computers, personal computers, etc. A wireless communication device may alternatively be referred to as an access terminal, a mobile terminal, a subscriber station, a remote station, a user terminal, a terminal, a subscriber unit, user equipment, a mobile station, etc.

A wireless communication network may provide communication for a number of wireless communication devices, each of which may be serviced by a base station. A base station may alternatively be referred to as an access point, a Node B, or some other terminology. Base stations and wireless communication devices may make use of multi-mode bandpass filters 102 implemented using multi-directional vibrating microelectromechanical systems (MEMS) resonators 104. However, many different kinds of electronic devices, in addition to the wireless devices mentioned, may make use of multi-mode bandpass filters 102 implemented using multi-directional vibrating microelectromechanical systems (MEMS) resonators 104.

The parallel multi-directional vibrating microelectromechanical systems (MEMS) resonator 104a may include multiple conductive electrodes. The parallel multi-directional vibrating microelectromechanical systems (MEMS) resonator 104a may also include a piezoelectric material 116a sandwiched between conductive electrodes. In one configuration, the parallel multi-directional vibrating microelectromechanical systems (MEMS) resonator 104a may include one or more input electrodes 106a and one or more output electrodes 108a. As used herein, multi-directional vibrating refers to single-chip multi-frequency operation, in contrast with conventional quartz crystal and film bulk acoustic wave resonator (FBAR) technologies for which only one center frequency is allowed per wafer.

The parallel multi-directional vibrating microelectromechanical systems (MEMS) resonator 104a may be designed with a specific resonator width 110a, resonator thickness 112a and resonator length 114a corresponding to a piezoelectric material 116a of the parallel multi-directional vibrating microelectromechanical systems (MEMS) resonator 104a. Each of the resonator width 110a, resonator thickness 112a and resonator length 114a may be associated with a resonant frequency. Each resonant frequency may be determined by the period of a signal (e.g., an acoustic signal) reflecting from one end of the piezoelectric material 116a to another laterally along the resonator width 110a, vertically along the resonator thickness 112a or longitudinally along the resonator length 114a of the parallel multi-directional vibrating microelectromechanical systems (MEMS) resonator 104a. Because the resonator width 110a, resonator thickness 112a and resonator length 114a may be designed with different dimensions, the parallel multi-directional vibrating microelectromechanical systems (MEMS) resonator 104a may have three distinct resonant frequencies. Thus, the parallel multi-directional vibrating microelectromechanical systems (MEMS) resonator 104a may use the resonator width 110a, resonator thickness 112a and resonator length 114a to pass multiple frequencies.

The piezoelectric material 116a may translate input signal(s) from one or more electrodes into mechanical vibrations, which can be translated to the output signal(s). These mechanical vibrations may be the resonant frequencies of the multi-directional vibrating microelectromechanical systems (MEMS) resonators 104. Based on the resonator width 110a, resonator thickness 112a and resonator length 114a, the resonant frequencies of the parallel multi-directional vibrating microelectromechanical systems (MEMS) resonator 104a may be controlled. The fundamental frequency for the displacement of the piezoelectric material 116a may be set in part lithographically by the planar dimensions of the electrodes and/or the layer of the piezoelectric material 116a.

An electric field applied across the electrodes may induce mechanical deformation in one or more planes of the piezoelectric material 116a via one or more piezoelectric coefficients 120a, 122a, 124a. At the resonant frequencies of the parallel multi-directional vibrating microelectromechanical systems (MEMS) resonator 104a, the electrical signal (e.g., acoustic signal) across the device is reinforced and the device behaves as an electronic resonator circuit.

In one configuration, the piezoelectric material 116a may be made from aluminum nitride (AlN) and its alloys. Examples of MN alloys include boron (B), chromium (Cr), erbium (Er) or scandium (Sc). Other configurations may use different types of piezoelectric materials 116a. Examples of piezoelectric materials 116a may include lithium niobate (LiNbO3), lithium tantalate (LiTaO3), lead zirconate titanate (PZT), zinc oxide (ZnO), quartz, etc.

In general, a piezoelectric material 116 may include various properties. For example, the piezoelectric material 116a of the parallel multi-directional vibrating microelectromechanical systems (MEMS) resonator 104a may have a quality factor (Q) 118a, piezoelectric coefficients 120a, 122a, 124a, and an electromechanical coupling (kt²) 126a. In some configurations, where the piezoelectric material 116a includes different values of piezoelectric coefficients 120a, 122a, 124a, the piezoelectric material 116a may include multiple quality factor (Q) 118a values and electromechanical coupling (kt²) 126a values corresponding to each of the piezoelectric coefficients 120a, 122a, 124a. The piezoelectric coefficient is defined as the electric displacement of a piezoelectric material 116a induced by a unit of applied stress. When both the stress and electric displacement are along the poling direction, the piezoelectric coefficient may be referred to as the longitudinal piezoelectric coefficient (d₃₃) 124a. When the stress is applied along the length of the sample and the electrical displacement is induced along the thickness direction, the piezoelectric coefficient may be referred to as the first transverse piezoelectric coefficient (d₃₁) 120a. When the stress is applied along the width of the sample and the electrical displacement is induced along the thickness direction, the piezoelectric coefficient may be referred to as the second transverse piezoelectric coefficient (d₃₂) 122a.

The product of an electromechanical coupling (kt²) 126 and a quality factor (Q) 118 is the figure of merit (FOM) of a piezoelectric material 116. When the figure of merit (FOM) is a high value, there is a lower motional resistance (Rm), and therefore a lower filter insertion loss. Conversely, if the product of the electromechanical coupling (kt²) 126 and the quality factor (Q) 118 is low, resulting in a low figure of merit (FOM), there will be a higher motional resistance (Rm), and therefore a higher filter insertion loss. The electromechanical coupling (kt²) 126 and the quality factor 118 may vary independently from each other. Further, because each of the piezoelectric coefficients may have different values, each resonant frequency may be associated with a different electromechanical coupling (kt²) 126 value and quality factor (Q) 118. Consequently, the parallel multi-directional vibrating microelectromechanical systems (MEMS) resonator 104a may include multiple quality factor (Q) 118a values and multiple electromechanical coupling (kt²) values 126a.

In one configuration, the total width multiplied by the total length of the parallel multi-directional vibrating microelectromechanical systems (MEMS) resonator 104a may be set to control the impedance of the resonator structure. A suitable thickness of the piezoelectric material 116a may be 0.01 to 10 micrometers (μm) thick.

The series multi-directional vibrating microelectromechanical systems (MEMS) resonator 104b may include multiple conductive electrodes. The series multi-directional vibrating microelectromechanical systems (MEMS) resonator 104b may also include a piezoelectric material 116b sandwiched between the conductive electrodes. The series multi-directional vibrating microelectromechanical systems (MEMS) resonator 104b may include one or more input electrodes 106b and one or more output electrodes 108b. In one configuration, the series multi-directional vibrating microelectromechanical systems (MEMS) resonator 104b may include a piezoelectric material 116b and a configuration of electrodes similar to that of the parallel multi-directional vibrating microelectromechanical systems (MEMS) resonator 104a.

The series multi-directional vibrating microelectromechanical systems (MEMS) resonator 104b may be designed with a specific resonator width 110b, resonator thickness 112b and resonator length 114b. Each of the resonator width 110b, resonator thickness 112b and resonator length 114b may be associated with a resonant frequency. Because the resonator width 110b, resonator thickness 112b and resonator length 114b may be designed with different dimensions, the series multi-directional vibrating microelectromechanical systems (MEMS) resonator 104b may have three distinct resonant frequencies. Thus, the series multi-directional vibrating microelectromechanical systems (MEMS) resonator 104b may use the resonator width 110b, resonator thickness 112b and resonator length 114b to pass multiple frequencies.

The piezoelectric material 116b may translate input signal(s) from one or more electrodes into mechanical vibrations, which can be translated to the output signal(s). These mechanical vibrations may be the resonant frequencies of the multi-directional vibrating microelectromechanical systems (MEMS) resonators 104. Based on the resonator width 110b, resonator thickness 112b and resonator length 114b, the resonant frequencies of the series multi-directional vibrating microelectromechanical systems (MEMS) resonator 104b may be controlled. The fundamental frequency for the displacement of the piezoelectric material 116b may be set in part lithographically by the planar dimensions of the electrodes and/or the layer of the piezoelectric material 116b.

An electric field applied across the electrodes may induce mechanical deformation along one or more planes of the piezoelectric material 116b via one or more of the piezoelectric coefficients 120b, 122b, 124b. At the resonant frequency of the series multi-directional vibrating microelectromechanical systems (MEMS) resonator 104b, the electrical signal (e.g., acoustic signal) across the device is reinforced and the device behaves as an electronic resonator circuit.

The dimensions of the series multi-directional vibrating microelectromechanical systems (MEMS) resonator 104b may be different from the dimensions of the parallel multi-directional vibrating microelectromechanical systems (MEMS) resonator 104a. Further, the dimensions of each of the multi-directional vibrating microelectromechanical systems (MEMS) resonators 104 may be designed to generate six different resonant frequencies corresponding to each of the different resonator widths 110, resonator thicknesses 112 and resonator lengths 114 of the parallel and series multi-directional vibrating microelectromechanical systems (MEMS) resonators 104a-b. In one configuration, the resonator width 110b, resonator thickness 112b and resonator length 114b of the series multi-directional vibrating microelectromechanical systems (MEMS) resonator 104b may be designed to produce three resonant frequencies that are offset from the three resonant frequencies of the parallel multi-directional vibrating microelectromechanical systems (MEMS) resonator 104a.

The combination of the parallel multi-directional vibrating microelectromechanical systems (MEMS) resonator 104a and the series multi-directional vibrating microelectromechanical systems (MEMS) resonator 104b may be used to synthesize three wideband (e.g., with a fractional bandwidth >3%) filters at various center frequencies (e.g., from 10 megahertz (MHz) up to microwave frequencies) on the same chip or with only using two multi-directional vibrating microelectromechanical systems (MEMS) resonators 104 for multi-band/multi-mode wireless communications. Multiple multi-directional vibrating microelectromechanical systems (MEMS) resonators 104 may be electrically (e.g., in a ladder, lattice or self-coupling topology) and/or mechanically coupled to synthesize high-order multi-mode bandpass filters with different center frequencies and bandwidths (narrow or wide). In one configuration, the parallel multi-directional vibrating microelectromechanical systems (MEMS) resonator 104a and the series multi-directional vibrating microelectromechanical systems (MEMS) resonator 104b are arranged using a ladder filter design. Other configurations may include additional ladder, lattice or self-coupling topologies. The multi-directional vibrating microelectromechanical systems (MEMS) resonators 104 may be on a single chip.

Different excitation schemes (e.g., lateral, vertical and longitudinal excitation) can be used to excite all different kinds of vibration modes (e.g., width-extensional, length-extensional, thickness-extensional, Lamb wave, shear mode, etc.) in multi-directional vibrating microelectromechanical systems (MEMS) resonators 104. In one configuration, the multi-mode bandpass filter 102 may function as a dual mode filter for passing two resonant frequencies. In another configuration, the multi-mode bandpass filter may function as a tri-mode filter for passing three resonant frequencies.

One benefit of such a construction is that multi-frequency RF filters, clock oscillators, transducers or other devices that each include one or more multi-directional vibrating microelectromechanical systems (MEMS) resonators 104 can be fabricated on the same substrate. This may be advantageous in terms of cost and size by enabling compact, multi-band filter solutions for RF front-end applications on a single chip. A multi-directional vibrating microelectromechanical systems (MEMS) resonator 104 may provide the advantages of compact size (e.g., 100 micrometers (μm) in length and/or width), low power consumption and compatibility with high-yield mass-producible components.

In some configurations, the piezoelectric material 116b of the series multi-directional vibrating microelectromechanical systems (MEMS) resonator 104b may be the same as the piezoelectric material 116a of the parallel multi-directional vibrating microelectromechanical systems (MEMS) resonator 104a. In another configuration, parallel multi-directional vibrating microelectromechanical systems (MEMS) resonator 104a and the series multi-directional vibrating microelectromechanical systems (MEMS) resonator 104b may each use different piezoelectric materials 116a-b.

The piezoelectric material 116b of the series multi-directional vibrating microelectromechanical systems (MEMS) resonator 104b may have a quality factor (Q) 118b, multiple piezoelectric coefficients 120b, 122b, 124b and an electromechanical coupling (kt²) 126b. In some configurations, where the piezoelectric material 116b includes different values of piezoelectric coefficients 120b, 122b, 124b, the piezoelectric material 116b may include multiple quality factor (Q) values 118b and electromechanical coupling (kt²) 126b values corresponding to each of the piezoelectric coefficients 120b, 122b, 124b.

Each piezoelectric coefficient 120b, 122b, 124b may quantify a volume change when the piezoelectric material 116b is subject to an electric field. As discussed above, examples of piezoelectric coefficients may include a first transverse piezoelectric coefficient (d₃₁) 120b, a second transverse piezoelectric coefficient (d₃₂) 122b and a longitudinal piezoelectric coefficient (d₃₃) 124b.

The parallel multi-directional vibrating microelectromechanical systems (MEMS) resonator 104a and the series multi-directional vibrating microelectromechanical systems (MEMS) resonator 104b may be used to generate a multi-mode bandpass filter 102 by placing the parallel multi-directional vibrating microelectromechanical systems (MEMS) resonator 104a and the series multi-directional vibrating microelectromechanical systems (MEMS) resonator 104b in a ladder filter topology configuration. In the ladder filter topology configuration, the parallel multi-directional vibrating microelectromechanical systems (MEMS) resonator 104a may be placed in a parallel configuration and the series multi-directional vibrating microelectromechanical systems (MEMS) resonator 104b may be placed in a series configuration.

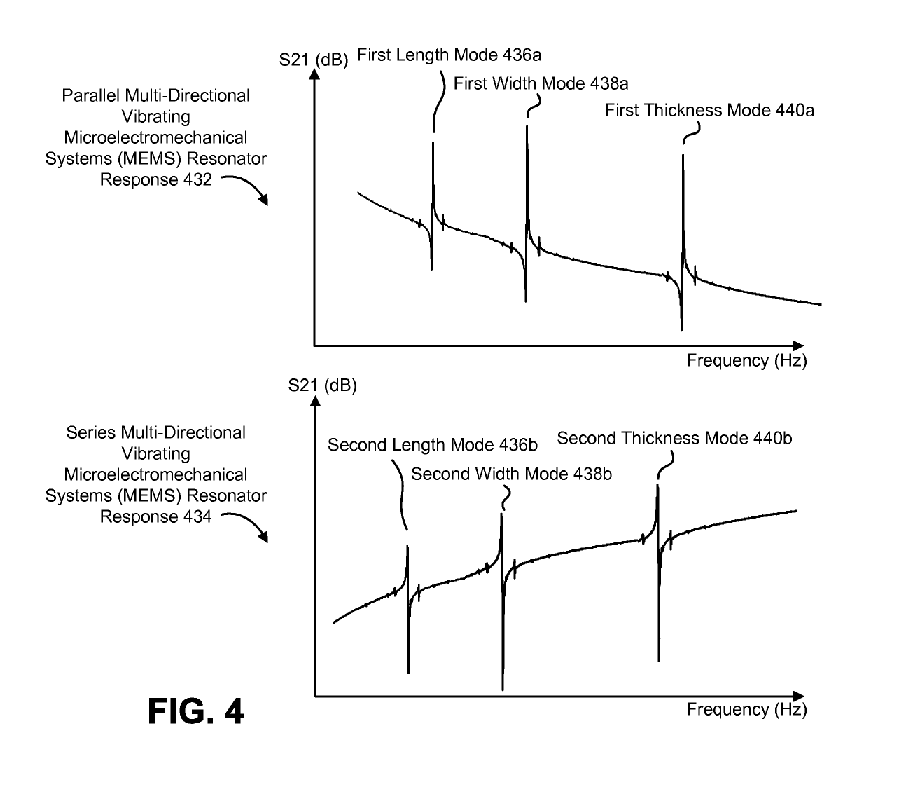

In some configurations of a multi-mode bandpass filter 102 implemented using a ladder filter topology, each of the multi-directional vibrating microelectromechanical systems (MEMS) resonators 104a-b may have one or more offset resonant frequencies. For example, the resonant frequencies associated with the resonator width 110a, resonator thickness 112a and resonator length 114a of the parallel multi-directional vibrating microelectromechanical systems (MEMS) resonator 104a may be offset from the resonant frequencies associated with the resonator width 110b, resonator thickness 112a and resonator length 114a of the series multi-directional vibrating microelectromechanical systems (MEMS) resonator 104b. Therefore, when placed in a ladder filter topology, the resonant frequencies may be offset along the frequency spectrum according to the differences in resonant frequencies. The frequency response for a multi-mode bandpass filter 102 with offset resonant frequencies may have two peaks for each resonant frequency that are offset according to the difference in the resonant frequencies of each multi-directional vibrating microelectromechanical systems (MEMS) resonator 104a-b. The frequency offset may be used in determining or obtaining a bandwidth of the multi-mode bandpass filter 102. The frequency responses of the parallel multi-directional vibrating microelectromechanical systems (MEMS) resonator 104a and the series multi-directional vibrating microelectromechanical systems (MEMS) resonator 104b are discussed in more detail below in connection with FIGS. 4-6.

Alternatively, in some configurations of a multi-mode bandpass filter 102 implemented using a ladder filter topology, each of the multi-directional vibrating microelectromechanical systems (MEMS) resonators 104a-b may have aligned resonant frequencies. For example, the resonant frequencies associated with the resonator width 110a, resonator thickness 112a and resonator length 114a of the parallel multi-directional vibrating microelectromechanical systems (MEMS) resonator 104a may be aligned with the resonant frequencies associated with the resonator width 110b, resonator thickness 112a and resonator length 114a of the series multi-directional vibrating microelectromechanical systems (MEMS) resonator 104b. Therefore, when placed in a ladder filter topology, the resonant frequencies may be aligned on the frequency spectrum according to similar resonant frequencies. The frequency response for a multi-mode bandpass filter 102 with aligned resonant frequencies may have a single peak at the aligned resonant frequencies of the multi-directional vibrating microelectromechanical systems (MEMS) resonators 104a-b. In some configurations, the bandwidth of the multi-mode bandpass filter 102 may be based at least partially on electromechanical coupling (kt²) values associated with each of the multi-directional vibrating microelectromechanical systems (MEMS) resonators 104a-b. The frequency responses of the parallel multi-directional vibrating microelectromechanical systems (MEMS) resonator 104a and the series multi-directional vibrating microelectromechanical systems (MEMS) resonator 104b are discussed in more detail below in connection with FIGS. 4-6.

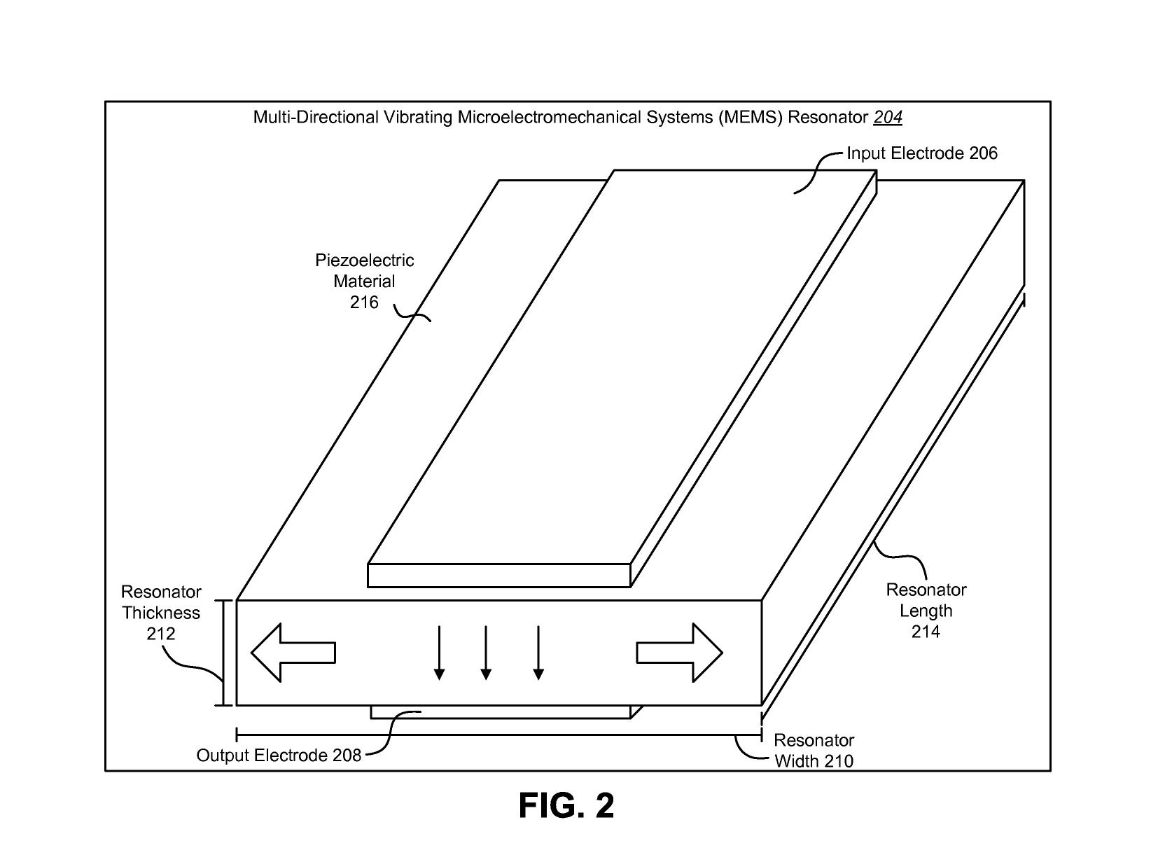

FIG. 2 is a block diagram illustrating a perspective view of a multi-directional vibrating microelectromechanical systems (MEMS) resonator 204. The multi-directional vibrating microelectromechanical systems (MEMS) resonator 204 of FIG. 2 may be one configuration of the parallel multi-directional vibrating microelectromechanical systems (MEMS) resonator 104a and/or series multi-directional vibrating microelectromechanical systems (MEMS) resonator 104b of FIG. 1. The multi-directional vibrating microelectromechanical systems (MEMS) resonator 204 may include an input electrode 206 and an output electrode 208. The multi-directional vibrating microelectromechanical systems (MEMS) resonator 204 may also include a piezoelectric material 216 sandwiched between the input electrode 206 and the output electrode 208. Thus, the input electrode 206 may be coupled to a first surface of the piezoelectric material 216 and the output electrode 208 may be coupled a second surface of the piezoelectric material 216.

An electric field applied across the input electrode 206 and the output electrode 208 may induce mechanical deformation along one or more planes of the piezoelectric material 216. The multi-directional vibrating microelectromechanical systems (MEMS) resonator 204 may be designed to pass specific resonant frequencies. Specifically, the multi-directional vibrating microelectromechanical systems (MEMS) resonator 204 may be designed according to a resonator width 210, a resonator thickness 212 and a resonator length 214. Each of the resonator width 210, resonator thickness 212 and resonator length 214 may be associated with a resonant frequency. At each of the resonant frequencies of the multi-directional vibrating microelectromechanical systems (MEMS) resonator 204, the electrical signal (e.g., acoustic signal) across the device is reinforced and the device behaves as an electronic resonator circuit. One or more of the multi-directional vibrating microelectromechanical systems (MEMS) resonators 204 may be implemented in a multi-mode bandpass filter 102.

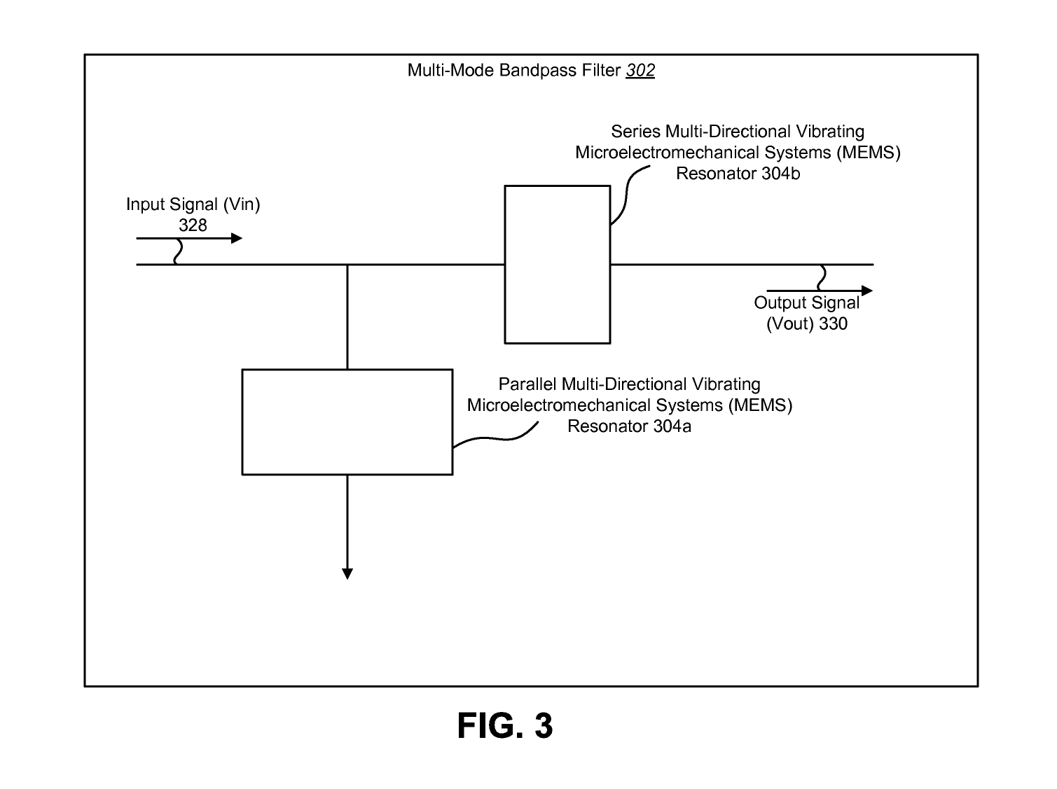

FIG. 3 is a circuit diagram illustrating one example of a multi-mode bandpass filter 302. The multi-mode bandpass filter 302 may include a parallel multi-directional vibrating microelectromechanical systems (MEMS) resonator 304a and a series multi-directional vibrating microelectromechanical systems (MEMS) resonator 304b in a ladder filter topology. The multi-mode bandpass filter 302 may receive an input signal (Vin) 328 and filter select resonant frequencies of the input signal (Vin) 328 to produce a filtered output signal (Vout) 330.

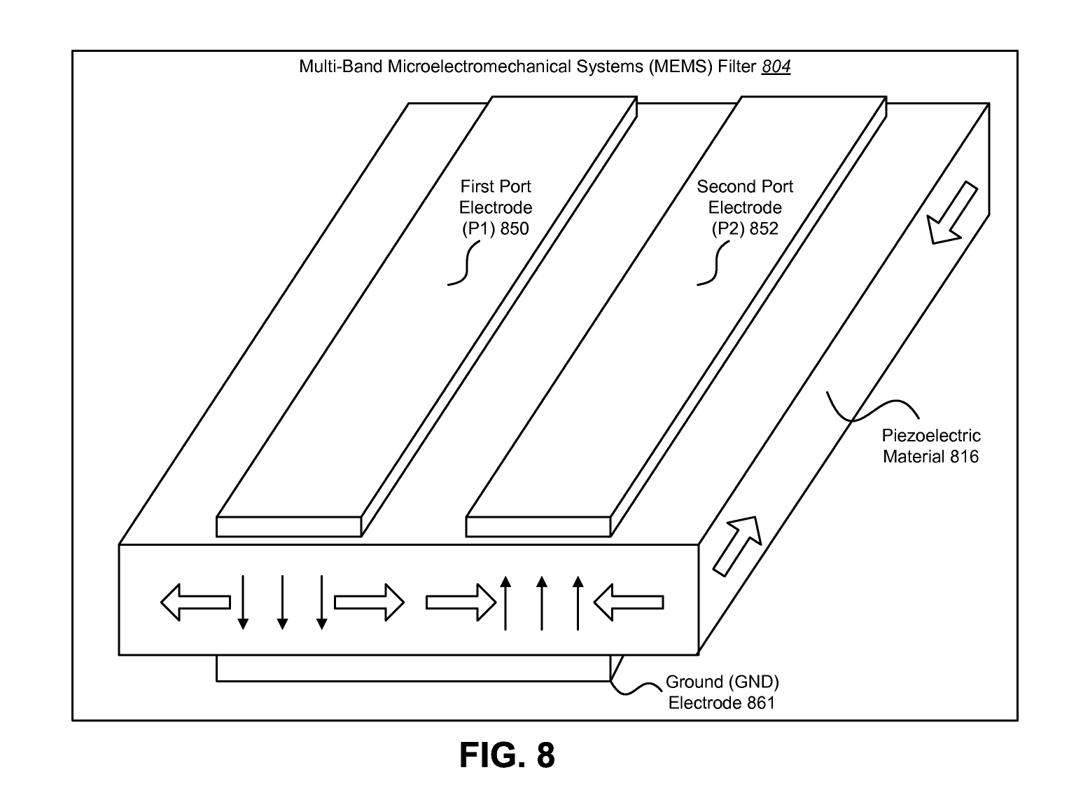

Different configurations of multi-directional vibrating microelectromechanical systems (MEMS) resonators 304 may be used in the multi-mode bandpass filter 302. For example, different electrode configurations and switching mode bias control can enhance the multi-band operation of the multi-mode bandpass filter 302. Further, different configurations may be used to cover more frequency bands if needed. Other configurations of electrodes and multi-directional vibrating microelectromechanical systems (MEMS) resonators 304 are described in more detail below in connection with FIGS. 8-13.

FIG. 4 illustrates graphs of the frequency responses of a parallel multi-directional vibrating microelectromechanical systems (MEMS) resonator 304a and a series multi-directional vibrating microelectromechanical systems (MEMS) resonator 304b. Each of the multi-directional vibrating microelectromechanical systems (MEMS) resonators 304 may be implemented in a multi-mode bandpass filter 302. The y-axis of each graph represents a magnitude of an S-parameter (S21) in decibels (dB). The x-axis of each graph represents a range of frequencies in hertz (Hz).

The parallel multi-directional vibrating microelectromechanical systems (MEMS) resonator response 432 depicts a frequency response of a parallel multi-directional vibrating microelectromechanical systems (MEMS) resonator 304a in the multi-mode bandpass filter 302 configuration of FIG. 3. The series multi-directional vibrating microelectromechanical systems (MEMS) resonator response 434 depicts a frequency response of a series multi-directional vibrating microelectromechanical systems (MEMS) resonator 304b in the multi-mode bandpass filter 302 configuration of FIG. 3.

The parallel multi-directional vibrating microelectromechanical systems (MEMS) resonator response 432 shows three different modes corresponding to three different resonant frequencies. The parallel multi-directional vibrating microelectromechanical systems (MEMS) resonator response 432 may include a first length mode 436a, a first width mode 438a and a first thickness mode 440a. Each of the modes may occur at various frequencies that depend on the resonator length 114a, resonator width 110a and resonator thickness 112a of the parallel multi-directional vibrating microelectromechanical systems (MEMS) resonator 304a. Because a lower frequency is associated with a larger dimension, the parallel multi-directional vibrating microelectromechanical systems (MEMS) resonator response 432 indicates that the resonator length 114a is larger than the resonator width 110a and the resonator thickness 112a. Furthermore, the parallel multi-directional vibrating microelectromechanical systems (MEMS) resonator response 432 also indicates that the resonator thickness 112a is less than the resonator width 110a and the resonator length 114a. Therefore, the first length mode 436a is associated with the lowest frequency and the first thickness mode 440a is associated with the highest frequency on the graph.

In one configuration, the first length mode 436a may occur at 20 MHz or less (e.g., 10 MHz). The first thickness mode 440a may occur between 900 MHz and 4.5 Gigahertz (GHz). The first width mode 438a may occur at some frequency between the first length mode 436a and the first thickness mode 440a. Specific resonant frequencies may be accomplished when generating the parallel multi-directional vibrating microelectromechanical systems (MEMS) resonator 304a according to a specific resonator width 110a, resonator thickness 112a and resonator length 114a.

The series multi-directional vibrating microelectromechanical systems (MEMS) resonator response 434 shows three different modes corresponding to three different resonant frequencies. The series multi-directional vibrating microelectromechanical systems (MEMS) resonator response 434 may include a second length mode 436b, a second width mode 438b and a second thickness mode 440b. Each of the modes may occur at different frequencies that depend on the resonator length 114b, resonator width 110b and resonator thickness 112b of the series multi-directional vibrating microelectromechanical systems (MEMS) resonator 304b. In one configuration, the series multi-directional vibrating microelectromechanical systems (MEMS) resonator 304b may be designed to have a second length mode 436b, second width mode 438b and second thickness mode 440b offset by a certain frequency range from the first length mode 436a, first width mode 438a and first thickness mode 440a of the parallel multi-directional vibrating microelectromechanical systems (MEMS) resonator 304a.

The parallel multi-directional vibrating microelectromechanical systems (MEMS) resonator response 432 may be vertically flipped in comparison to the series multi-directional vibrating microelectromechanical systems (MEMS) resonator response 434. The vertically flipped response is due to differences between the parallel orientation of the parallel multi-directional vibrating microelectromechanical systems (MEMS) resonator 304a and the series orientation of the series multi-directional vibrating microelectromechanical systems (MEMS) resonator 304b in the multi-mode bandpass filter 302. In some configurations, the respective responses may reflect the orientation of the multi-directional vibrating microelectromechanical systems (MEMS) resonators 304 implemented on the multi-mode bandpass filter 302.

The parallel multi-directional vibrating microelectromechanical systems (MEMS) resonator response 432 and series multi-directional vibrating microelectromechanical systems (MEMS) resonator response 434 may also be offset along the frequency spectrum. The offset between the parallel multi-directional vibrating microelectromechanical systems (MEMS) resonator response 432 and the series multi-directional vibrating microelectromechanical systems (MEMS) resonator response 434 may be due to the different dimensions between the resonator widths 110, resonator thicknesses 112 and resonator lengths 114 of each of the multi-directional vibrating microelectromechanical systems (MEMS) resonators 304.

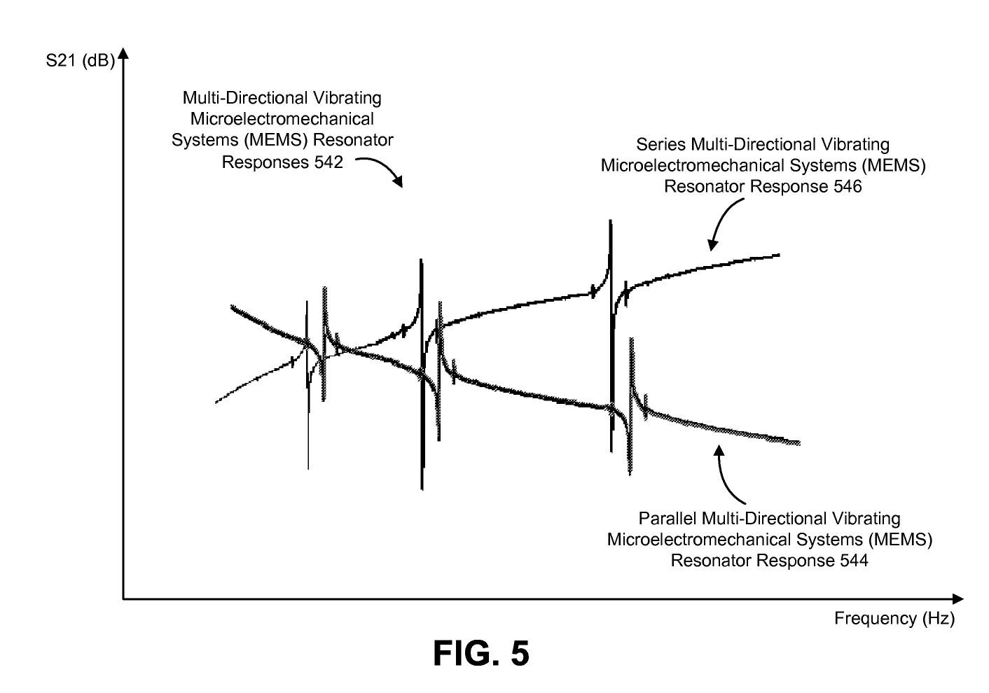

FIG. 5 illustrates a graph of frequency responses for two multi-directional vibrating microelectromechanical systems (MEMS) resonators 304. The multi-directional vibrating microelectromechanical systems (MEMS) resonator responses 542 may be similar to the frequency responses described above in connection with FIG. 4. The multi-directional vibrating microelectromechanical systems (MEMS) resonator responses 542 may include a parallel multi-directional vibrating microelectromechanical systems (MEMS) resonator response 544 and a series multi-directional vibrating microelectromechanical systems (MEMS) resonator response 546.

Each of the parallel multi-directional vibrating microelectromechanical systems (MEMS) resonator 304a and the series multi-directional vibrating microelectromechanical systems (MEMS) 304b may be designed to have offset length modes 436, width modes 438 and thickness modes 440. For example, the series multi-directional vibrating microelectromechanical systems (MEMS) resonator 304b may be designed with slightly smaller dimensions to produce a series multi-directional vibrating microelectromechanical systems (MEMS) resonator response 546 shifted to the right (in frequency) of the parallel multi-directional vibrating microelectromechanical systems (MEMS) resonator response 544. Offset frequencies in the multi-directional vibrating microelectromechanical systems (MEMS) responses 542 may enable the multi-mode bandpass filter 302 to pass multiple ranges of frequencies with varying bandwidths.

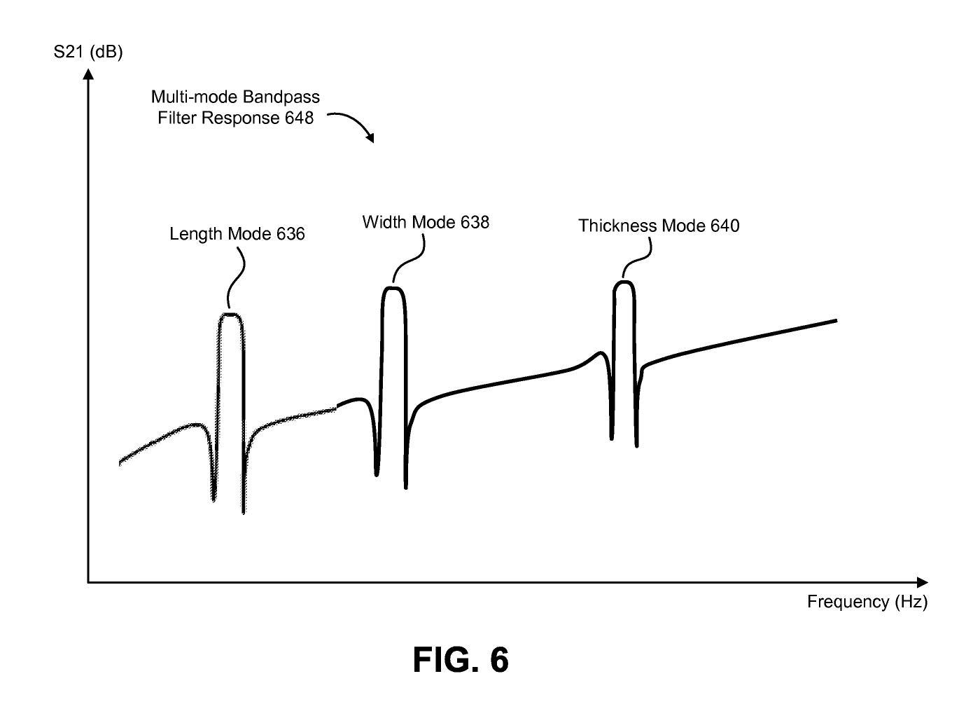

FIG. 6 illustrates a graph of a multi-mode bandpass filter response 648. The multi-mode bandpass filter response 648 of FIG. 6 may be one example of a combination of the multi-directional vibrating microelectromechanical systems (MEMS) resonator responses 432, 434, 542 described above in connection with FIGS. 4 and 5. Thus, the multi-mode bandpass filter response 648 shown may be the frequency response of the multi-mode bandpass filter 302 of FIG. 3. The multi-mode bandpass filter response 648 may include a length mode 636, a width mode 638 and a thickness mode 640. As opposed to the sharp responses corresponding to each of the individual multi-directional vibrating microelectromechanical systems (MEMS) resonator responses 542, the multi-mode bandpass filter 302 may pass multiple ranges of frequencies corresponding to the length mode 636, the width mode 638 and the thickness mode 640 of the multi-mode bandpass frequency response 648. Each of the modes may be altered by adjusting the dimensions of the multi-directional vibrating microelectromechanical systems (MEMS) resonators 304 implemented in the multi-mode bandpass filter 302.

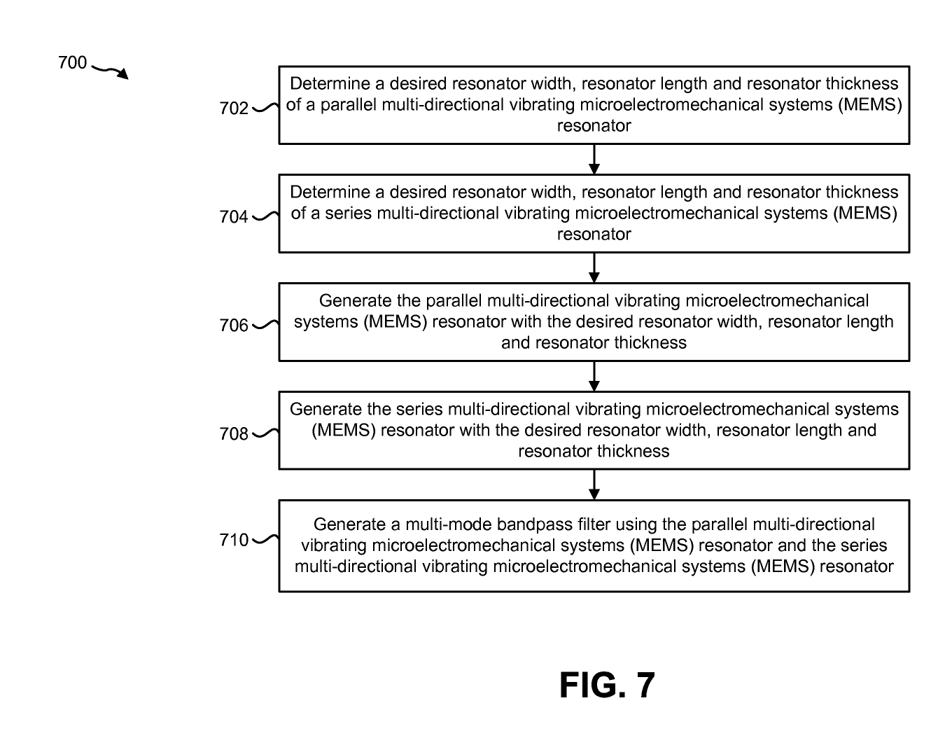

FIG. 7 is a flow diagram of a method 700 for generating a multi-mode bandpass filter 102. The method 700 may be performed by an engineer, technician or a computer. In one configuration, the method 700 may be performed by a fabrication machine.

A desired resonator width 110a, resonator length 114a and resonator thickness 112a of a parallel multi-directional vibrating microelectromechanical systems (MEMS) resonator 104a may be determined 702. A desired resonator width 110b, resonator length 114b and resonator thickness 112b of a series multi-directional vibrating microelectromechanical systems (MEMS) resonator 104b may also be determined 704. The parallel multi-directional vibrating microelectromechanical systems (MEMS) resonator 104a with the desired resonator width 110a, resonator length 114a and resonator thickness 112a may be generated 706. The series multi-directional vibrating microelectromechanical systems (MEMS) resonator 104b with the desired resonator width 110b, resonator length 114b and resonator thickness 112b may also be generated 708. A multi-mode bandpass filter 102 may then be generated 710 using the parallel multi-directional vibrating microelectromechanical systems (MEMS) resonator 104a and the series multi-directional vibrating microelectromechanical systems (MEMS) resonator 104b.

FIG. 8 is a diagram illustrating a perspective view of one configuration of a multi-band microelectromechanical systems (MEMS) filter 804. The multi-band microelectromechanical systems (MEMS) filter 804 may include a first port electrode (P1) 850 and a second port electrode (P2) 852. The multi-band microelectromechanical systems (MEMS) filter 804 may also include a ground (GND) electrode 861. The multi-band microelectromechanical systems (MEMS) filter 804 may further include a piezoelectric material 816.

The piezoelectric material 816 may be sandwiched between the first port electrode (P1) 850, the second port electrode (P2) 852 and the ground (GND) electrode 861. For example, the first port electrode (P1) 850 may be located directly above the ground (GND) electrode 861, with the piezoelectric material 816 in between. Likewise, the second port electrode (P2) 852 may be located directly above the ground (GND) electrode 861, with the piezoelectric material 816 in between. An electric field may be applied across the electrodes inducing mechanical deformation in one or more planes of the piezoelectric material 816. The electric field may pass between the first port electrode (P1) 850 and the ground (GND) electrode 861. The electric field may also pass between the ground (GND) electrode 861 and the second port electrode (P2) 852. The multi-band microelectromechanical systems (MEMS) filter 804 may be configured to filter multiple frequencies based on the resonant frequencies associated with a resonator width 110, resonator length 114 and resonator thickness 112 of the multi-band microelectromechanical systems (MEMS) filter 804.

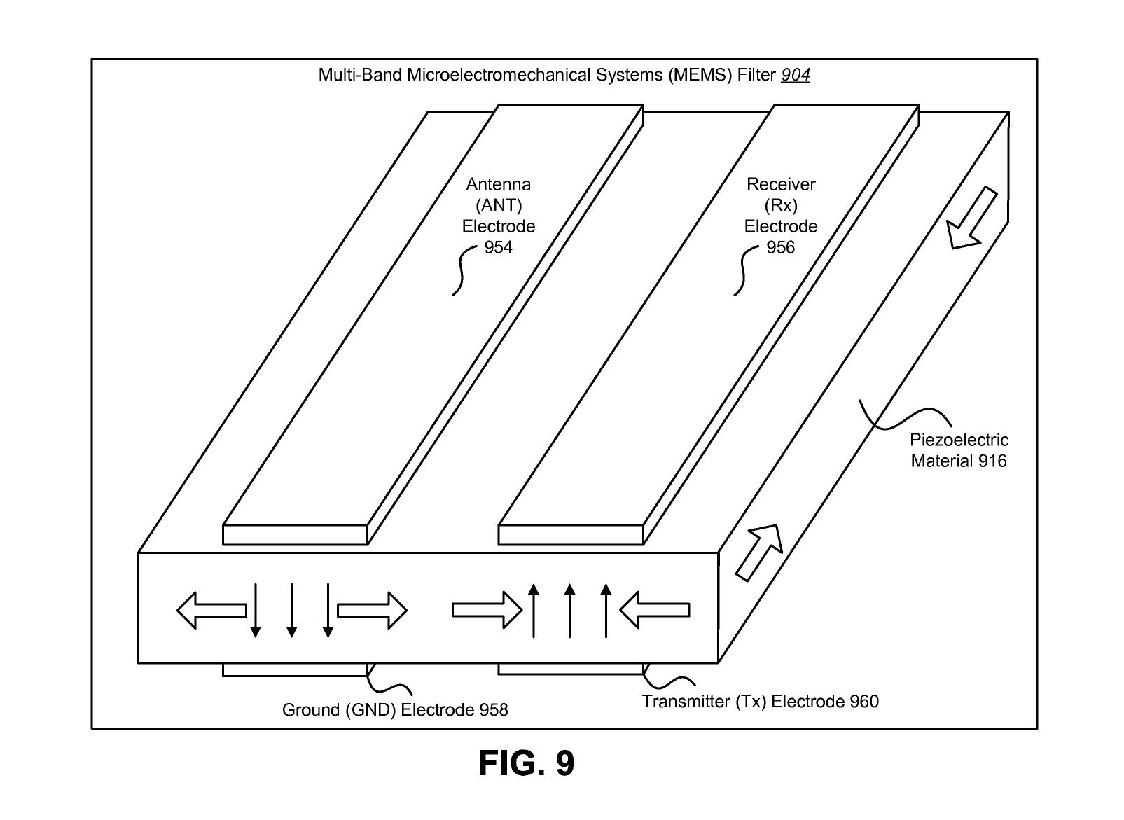

FIG. 9 is a diagram illustrating a perspective view of another configuration of a multi-band microelectromechanical systems (MEMS) filter 904. The multi-band microelectromechanical systems (MEMS) filter 904 may include an antenna (ANT) electrode 954 and a receiver (Rx) electrode 956. The multi-band microelectromechanical systems (MEMS) filter 904 may also include a ground (GND) electrode 958 and a transmitter (Tx) electrode 960. The multi-band microelectromechanical systems (MEMS) filter 904 may further include a piezoelectric material 916.

The piezoelectric material 916 may be sandwiched between the antenna (ANT) electrode 954, the receiver (Rx) electrode 956, the ground (GND) electrode 958 and the transmitter (Tx) electrode 960. For example, the antenna (ANT) electrode 954 may be located directly above the ground (GND) electrode 958, with the piezoelectric material 916 in between. Likewise, the receiver (Rx) electrode 956 may be located directly above the transmitter (Tx) electrode 960 with the piezoelectric material 916 in between. An electric field may be applied between electrodes across the piezoelectric material 916 inducing mechanical deformation in one or more planes of the piezoelectric material 916. The electric field may pass between the antenna (ANT) electrode 954 and the ground (GND) electrode 958. The electric field may also pass between the transmitter (Tx) electrode 960 and the receiver (Rx) electrode 956. The multi-band microelectromechanical systems (MEMS) filter 904 may be configured to filter multiple frequencies based on the resonant frequencies associated with a resonator width 110, resonator length 114 and resonator thickness 112 of the multi-band microelectromechanical systems (MEMS) filter 904.

Because the multi-band microelectromechanical systems (MEMS) filter 904 includes a receiver (Rx) electrode 956 and a transmitter (Tx) electrode 960, the multi-band microelectromechanical systems (MEMS) filter 904 may be configured as a multi-band duplexer. The multi-band microelectromechanical systems (MEMS) filter 904 may also include a switch coupled to the receiver (Rx) electrode 956 and a switch coupled to the transmitter (Tx) electrode 960. The multi-band microelectromechanical systems (MEMS) filter 904 may be configured to perform a different function by switching the potentials of the receiver (Rx) electrode 956 and the transmitter (Tx) electrode 960. For example, when the transmitter (Tx) electrode 960 is switched to ground (GND), the multi-band microelectromechanical systems (MEMS) filter 904 may behave similarly to the configuration of the multi-band microelectromechanical systems (MEMS) filter 804 described above in connection with FIG. 8. In another example, the receiver (Rx) electrode 956 may be switched to ground (GND), resulting in the antenna (ANT) electrode 954 behaving similarly to the first port electrode (P1) 850 and the transmitter (Tx) electrode 960 behaving similarly to the second port electrode (P2) 852 describe above in connection with FIG. 8. Other configurations may be used when the multi-band microelectromechanical systems (MEMS) filter 904 is implemented in an electronic device (e.g., a wireless communication device).

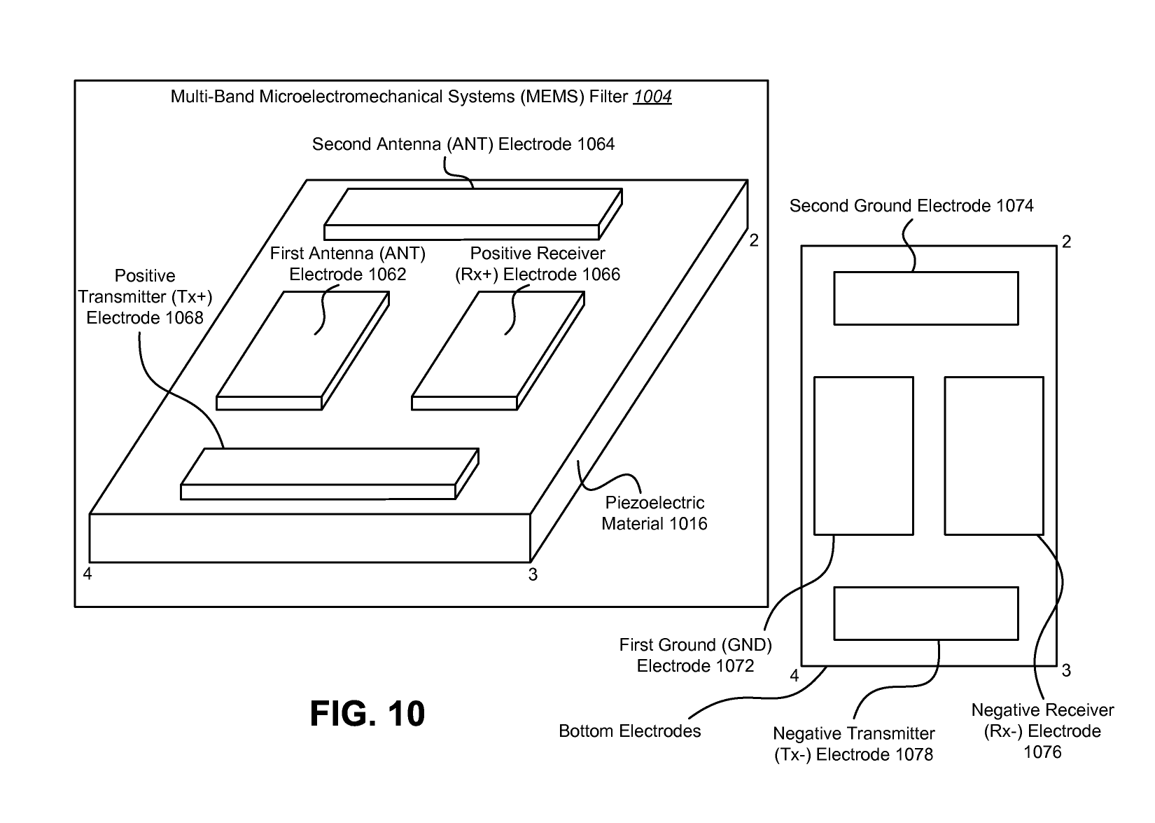

FIG. 10 is a diagram illustrating a perspective view of yet another configuration of a multi-band microelectromechanical systems (MEMS) filter 1004. Both the top electrodes and the bottom electrodes of the multi-band microelectromechanical systems (MEMS) filter 1004 are illustrated.

On a top side of a piezoelectric material 1016, the multi-band microelectromechanical systems (MEMS) filter 1004 may include a first antenna (ANT) electrode 1062, a second antenna (ANT) electrode 1064, a positive receiver (Rx+) electrode 1066 and a positive transmitter (Tx+) electrode 1068. On a bottom side of the piezoelectric material 1016, the multi-band microelectromechanical systems (MEMS) filter 1004 may include a first ground (GND) electrode 1072, a second ground electrode 1074, a negative receiver (Rx−) electrode 1076 and a negative transmitter (Tx−) electrode 1078. In some configurations, other components, such as switches, may be coupled to each of the electrodes of the multi-band microelectromechanical systems (MEMS) filter 1004.

An orientation of the multi-band microelectromechanical systems (MEMS) filter 1004 is indicated by reference points 2, 3 and 4. The piezoelectric material 1016 may be sandwiched between the first antenna (ANT) electrode 1062, the second antenna (ANT) electrode 1064, the positive receiver (Rx+) electrode 1066, the positive transmitter (Tx+) electrode 1068, the first ground (GND) electrode 1072, the second ground electrode 1074, the negative receiver (Rx−) electrode 1076 and the negative transmitter (Tx−) electrode 1078. The first antenna (ANT) electrode 1062 may be located directly above the first ground (GND) electrode 1072, with the piezoelectric material 1016 in between. The second antenna (ANT) electrode 1064 may be located directly above the second ground (GND) electrode 1074, with the piezoelectric material 1016 in between. The positive receiver (Rx+) electrode 1066 may be located directly above the negative receiver (Rx−) electrode 1076, with the piezoelectric material 1016 in between. Likewise, the positive transmitter (Tx+) electrode 1068 may be located directly above the negative transmitter (Tx−) electrode 1078, with the piezoelectric material 1016 in between. The multi-band microelectromechanical systems (MEMS) filter 1004 may be configured to filter multiple frequencies based on the resonant frequencies associated with a resonator width 110, resonator length 114 and resonator thickness 112 of the multi-band microelectromechanical systems (MEMS) filter 1004.

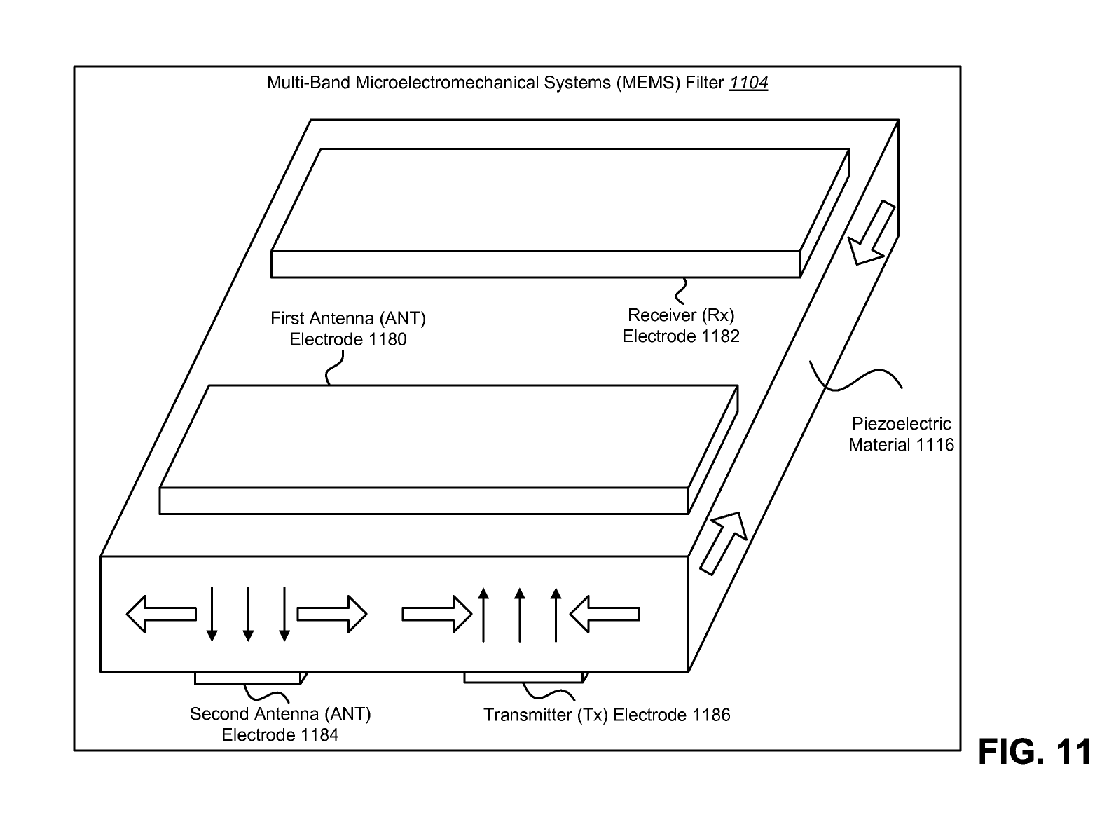

FIG. 11 is a diagram illustrating a perspective view of another configuration of a multi-band microelectromechanical systems (MEMS) filter 1104. The multi-band microelectromechanical systems (MEMS) filter 1104 may include a first antenna (ANT) electrode 1180, a receiver (Rx) electrode 1182, a second antenna (ANT) electrode 1184 and a transmitter (Tx) electrode 1186. The multi-band microelectromechanical systems (MEMS) filter 1104 may also include a piezoelectric material 1116.

The piezoelectric material 1116 may be sandwiched between the first antenna (ANT) electrode 1180, the receiver (Rx) electrode 1182, the second antenna (ANT) electrode 1184 and the transmitter (Tx) electrode 1186. For example, the first antenna (ANT) electrode 1180 and the receiver (Rx) electrode 1182 may both be located above the second antenna (ANT) electrode 1184 and the transmitter (Tx) electrode 1186, with the piezoelectric material 1116 in between. Further, the first antenna (ANT) electrode 1180 and the receiver (Rx) electrode 1182 may run long the width of the piezoelectric material 1116 while the second antenna (ANT) electrode 1184 and the transmitter (Tx) electrode 1186 run along the length of the piezoelectric material 1116. An electric field may be applied between electrodes across the piezoelectric material 1116 inducing mechanical deformation in one or more planes of the piezoelectric material 1116. The electric field may pass between each of the first antenna (ANT) electrode 1180 and the receiver (Rx) electrode 1182 on a first side of the piezoelectric material 1116 and each of the second antenna (ANT) electrode 1184 and the transmitter (Tx) electrode 1186 on a second side of the piezoelectric material 1116. The multi-band microelectromechanical systems (MEMS) filter 1104 may be configured to filter multiple frequencies based on the resonant frequencies associated with a resonator width 110, resonator length 114 and resonator thickness 112 of the multi-band microelectromechanical systems (MEMS) filter 1104.

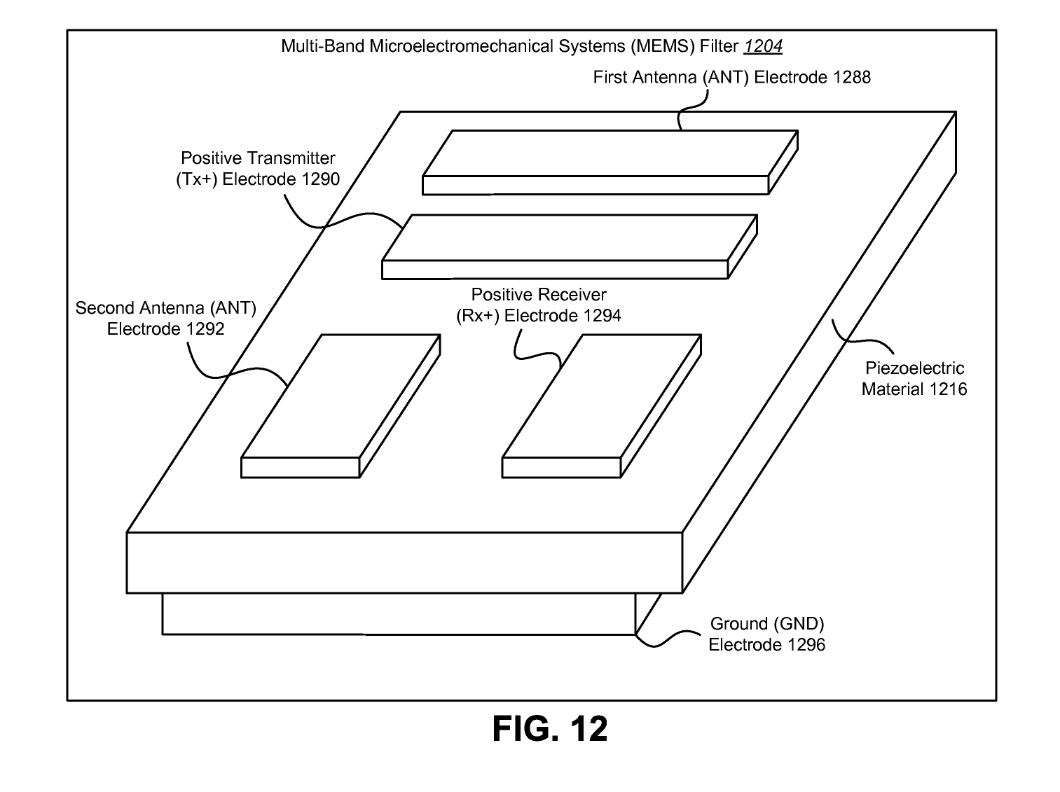

FIG. 12 is a diagram illustrating a perspective view of yet another configuration of a multi-band microelectromechanical systems (MEMS) filter 1204. The multi-band microelectromechanical systems (MEMS) filter 1204 may include a first antenna (ANT) electrode 1288, a positive transmitter (Tx+) electrode 1290, a second antenna (ANT) electrode 1292 a positive receiver (Rx+) electrode 1294 and a ground (GND) electrode 1296. The multi-band microelectromechanical systems (MEMS) filter 1204 may also include a piezoelectric material 1216.

The piezoelectric material 1216 may be sandwiched between the first antenna (ANT) electrode 1288, the positive transmitter (Tx+) electrode 1290, the second antenna (ANT) electrode 1292, the positive receiver (Rx+) electrode 1294 and the ground (GND) electrode 1296. For example, the first antenna (ANT) electrode 1288, positive transmitter (Tx+) electrode 1290, second antenna (ANT) electrode 1292 and the positive receiver (Rx+) electrode 1294 may be positioned directly above the ground (GND) electrode 1296 with the piezoelectric material 1216 in between. The multi-band microelectromechanical systems (MEMS) filter 1204 may be configured to filter multiple frequencies based on the resonant frequencies associated with a resonator width 110, resonator length 114 and resonator thickness 112 of the multi-band microelectromechanical systems (MEMS) filter 1204.

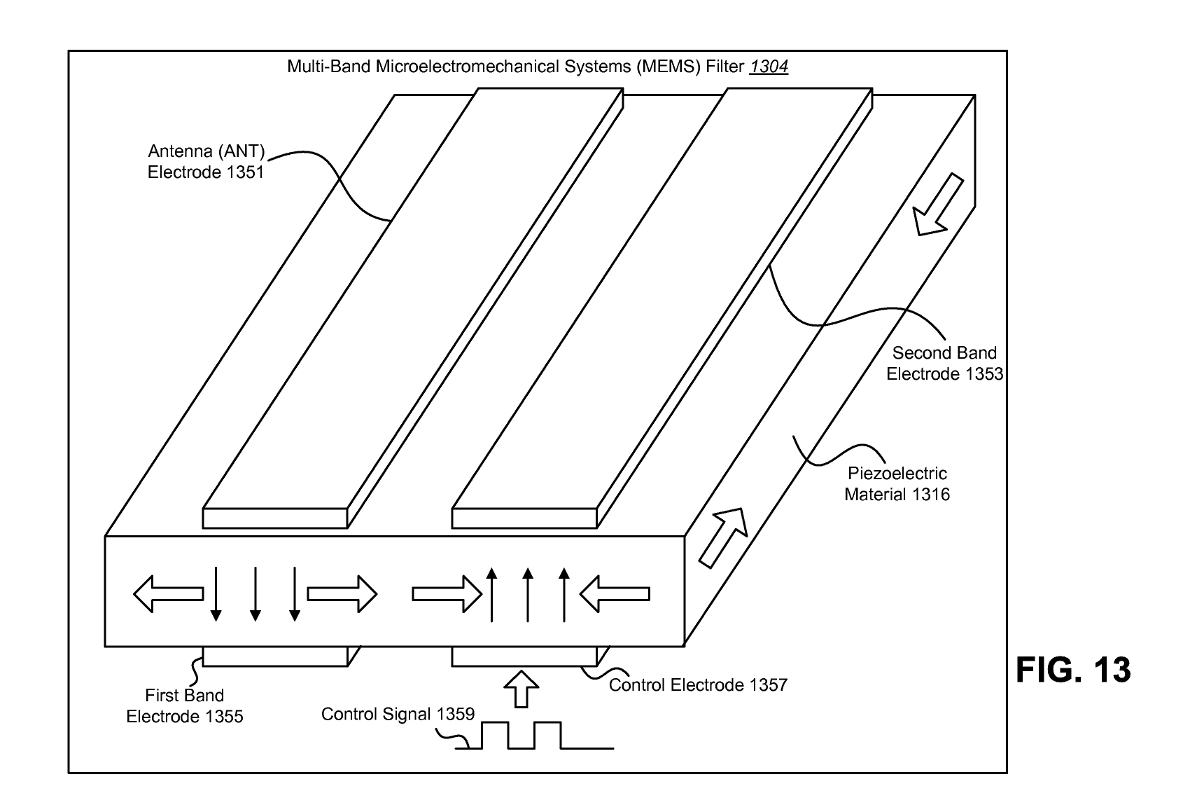

FIG. 13 is a diagram illustrating a perspective view of another configuration of a multi-band microelectromechanical systems (MEMS) filter 1304. The multi-band microelectromechanical systems (MEMS) filter 1304 may include an antenna (ANT) electrode 1351, a first band electrode 1355, a second band electrode 1353 and a control electrode 1357. The multi-band microelectromechanical systems (MEMS) filter 1304 may further include a piezoelectric material 1316.

The piezoelectric material 1316 may be sandwiched between the antenna (ANT) electrode 1351, the first band electrode 1355, the second band electrode 1353 and the control electrode 1357. For example, the antenna (ANT) electrode 1351 may be positioned directly above the first band electrode 1355, with the piezoelectric material 1316 in between. Likewise, the second band electrode 1353 may be positioned directly above the control electrode 1357, with the piezoelectric material 1316 in between. An electric field may be applied between electrodes across the piezoelectric material 1316, inducing mechanical deformation in one or more planes of the piezoelectric material 1316. An electric field may pass between the antenna (ANT) electrode 1351 and the first band electrode 1355. An electric field may also pass between the control electrode 1357 and the second band electrode 1353. In one configuration, a control signal 1359 may be applied to the control electrode 1357 for changing properties of an electric field passing through the piezoelectric material 1316. The multi-band microelectromechanical systems (MEMS) filter 1304 may be configured to filter multiple frequencies based on the resonant frequencies associated with a resonator width 110, resonator length 114 and resonator thickness 112 of the multi-band microelectromechanical systems (MEMS) filter 1304.

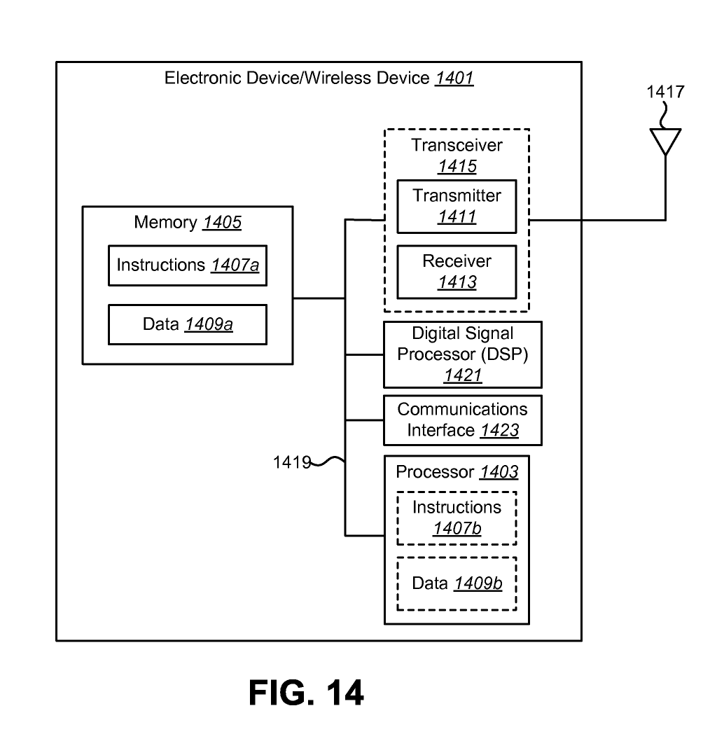

FIG. 14 illustrates certain components that may be included within an electronic device/wireless device 1401. The electronic device/wireless device 1401 may be an access terminal, a mobile station, a wireless communication device, a base station, a Node B, a handheld electronic device, etc. The electronic device/wireless device 1401 includes a processor 1403. The processor 1403 may be a general purpose single- or multi-chip microprocessor (e.g., an ARM), a special purpose microprocessor (e.g., a digital signal processor (DSP)), a microcontroller, a programmable gate array, etc. The processor 1403 may be referred to as a central processing unit (CPU). Although just a single processor 1403 is shown in the electronic device/wireless device 1401 of FIG. 14, in an alternative configuration, a combination of processors (e.g., an ARM and DSP) could be used.

The electronic device/wireless device 1401 also includes memory 1405. The memory 1405 may be any electronic component capable of storing electronic information. The memory 1405 may be embodied as random access memory (RAM), read-only memory (ROM), magnetic disk storage media, optical storage media, flash memory devices in RAM, on-board memory included with the processor, EPROM memory, EEPROM memory, registers, and so forth, including combinations thereof.

Data 1409a and instructions 1407a may be stored in the memory 1405. The instructions 1407a may be executable by the processor 1403 to implement the methods disclosed herein. Executing the instructions 1407a may involve the use of the data 1409a that is stored in the memory 1405. When the processor 1403 executes the instructions 1407a, various portions of the instructions 1407b may be loaded onto the processor 1403, and various pieces of data 1409b may be loaded onto the processor 1403.

The electronic device/wireless device 1401 may also include a transmitter 1411 and a receiver 1413 to allow transmission and reception of signals to and from the electronic device/wireless device 1401. The transmitter 1411 and receiver 1413 may be collectively referred to as a transceiver 1415. An antenna 1417 may be electrically coupled to the transceiver 1415. The electronic device/wireless device 1401 may also include (not shown) multiple transmitters, multiple receivers, multiple transceivers and/or multiple antennas.

The electronic device/wireless device 1401 may include a digital signal processor (DSP) 1421. The electronic device/wireless device 1401 may also include a communications interface 1423. The communications interface 1423 may allow a user to interact with the electronic device/wireless device 1401.

The various components of the electronic device/wireless device 1401 may be coupled together by one or more buses, which may include a power bus, a control signal bus, a status signal bus, a data bus, etc. For the sake of clarity, the various buses are illustrated in FIG. 14 as a bus system 1419.

The techniques described herein may be used for various communication systems, including communication systems that are based on an orthogonal multiplexing scheme. Examples of such communication systems include Orthogonal Frequency Division Multiple Access (OFDMA) systems, Single-Carrier Frequency Division Multiple Access (SC-FDMA) systems, and so forth. An OFDMA system utilizes orthogonal frequency division multiplexing (OFDM), which is a modulation technique that partitions the overall system bandwidth into multiple orthogonal sub-carriers. These sub-carriers may also be called tones, bins, etc. With OFDM, each sub-carrier may be independently modulated with data. An SC-FDMA system may utilize interleaved FDMA (IFDMA) to transmit on sub-carriers that are distributed across the system bandwidth, localized FDMA (LFDMA) to transmit on a block of adjacent sub-carriers, or enhanced FDMA (EFDMA) to transmit on multiple blocks of adjacent sub-carriers. In general, modulation symbols are sent in the frequency domain with OFDM and in the time domain with SC-FDMA.

The term “determining” encompasses a wide variety of actions and, therefore, “determining” can include calculating, computing, processing, deriving, investigating, looking up (e.g., looking up in a table, a database or another data structure), ascertaining and the like. Also, “determining” can include receiving (e.g., receiving information), accessing (e.g., accessing data in a memory) and the like. Also, “determining” can include resolving, selecting, choosing, establishing and the like.

The phrase “based on” does not mean “based only on,” unless expressly specified otherwise. In other words, the phrase “based on” describes both “based only on” and “based at least on.”

The term “processor” should be interpreted broadly to encompass a general purpose processor, a central processing unit (CPU), a microprocessor, a digital signal processor (DSP), a controller, a microcontroller, a state machine, and so forth. Under some circumstances, a “processor” may refer to an application specific integrated circuit (ASIC), a programmable logic device (PLD), a field programmable gate array (FPGA), etc. The term “processor” may refer to a combination of processing devices, e.g., a combination of a DSP and a microprocessor, a plurality of microprocessors, one or more microprocessors in conjunction with a DSP core, or any other such configuration.

The term “memory” should be interpreted broadly to encompass any electronic component capable of storing electronic information. The term memory may refer to various types of processor-readable media such as random access memory (RAM), read-only memory (ROM), non-volatile random access memory (NVRAM), programmable read-only memory (PROM), erasable programmable read-only memory (EPROM), electrically erasable PROM (EEPROM), flash memory, magnetic or optical data storage, registers, etc. Memory is said to be in electronic communication with a processor if the processor can read information from and/or write information to the memory. Memory that is integral to a processor is in electronic communication with the processor.

The terms “instructions” and “code” should be interpreted broadly to include any type of computer-readable statement(s). For example, the terms “instructions” and “code” may refer to one or more programs, routines, sub-routines, functions, procedures, etc. “Instructions” and “code” may comprise a single computer-readable statement or many computer-readable statements.

The functions described herein may be implemented in software or firmware being executed by hardware. The functions may be stored as one or more instructions on a computer-readable medium. The terms “computer-readable medium” or “computer-program product” refers to any tangible storage medium that can be accessed by a computer or a processor. By way of example, and not limitation, a computer-readable medium may include RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Disk and disc, as used herein, includes compact disc (CD), laser disc, optical disc, digital versatile disc (DVD), floppy disk and Blu-Ray® disc where disks usually reproduce data magnetically, while discs reproduce data optically with lasers. It should be noted that a computer-readable medium may be tangible and non-transitory. The term “computer-program product” refers to a computing device or processor in combination with code or instructions (e.g., a “program”) that may be executed, processed or computed by the computing device or processor. As used herein, the term “code” may refer to software, instructions, code or data that is/are executable by a computing device or processor.

The methods disclosed herein comprise one or more steps or actions for achieving the described method. The method steps and/or actions may be interchanged with one another without departing from the scope of the claims. In other words, unless a specific order of steps or actions is required for proper operation of the method that is being described, the order and/or use of specific steps and/or actions may be modified without departing from the scope of the claims.

Further, it should be appreciated that modules and/or other appropriate means for performing the methods and techniques described herein, such as those illustrated by FIG. 7, can be downloaded and/or otherwise obtained by a device. For example, a device may be coupled to a server to facilitate the transfer of means for performing the methods described herein. Alternatively, various methods described herein can be provided via a storage means (e.g., random access memory (RAM), read-only memory (ROM), a physical storage medium such as a compact disc (CD) or floppy disk, etc.), such that a device may obtain the various methods upon coupling or providing the storage means to the device.

It is to be understood that the claims are not limited to the precise configuration and components illustrated above. Various modifications, changes and variations may be made in the arrangement, operation and details of the systems, methods, and apparatus described herein without departing from the scope of the claims.

What is claimed is:

1. A multi-mode bandpass filter, comprising:
a first multi-directional vibrating microelectromechanical systems resonator; and
a second multi-directional vibrating microelectromechanical systems resonator, wherein the first multi-directional vibrating microelectromechanical systems resonator is in a parallel configuration and the second multi-directional vibrating microelectromechanical systems resonator is in a series configuration.

2. The multi-mode bandpass filter of claim 1, wherein each multi-directional vibrating microelectromechanical systems resonator comprises:
a piezoelectric material;
a first electrode on a first surface of the piezoelectric material; and
a second electrode on a second surface of the piezoelectric material.

3. The multi-mode bandpass filter of claim 2, wherein an electric field applied across the first electrode and the second electrode induces mechanical deformation in at least one plane of the piezoelectric material.

4. The multi-mode bandpass filter of claim 2, wherein the piezoelectric material comprises one of aluminum nitride, lithium niobate, lithium tantalate, lead zirconate titanate, zinc oxide and quartz.

5. The multi-mode bandpass filter of claim 2, wherein the first electrode is an input electrode, and wherein the second electrode is an output electrode.

6. The multi-mode bandpass filter of claim 2, wherein each multi-directional vibrating microelectromechanical systems resonator has a first transverse piezoelectric coefficient, a second transverse piezoelectric coefficient and a longitudinal piezoelectric coefficient for the piezoelectric material.

7. The multi-mode bandpass filter of claim 6, wherein each first transverse piezoelectric coefficient, second transverse piezoelectric coefficient and longitudinal piezoelectric coefficient of each multi-directional vibrating microelectromechanical systems resonator is associated with a resonant frequency.

8. The multi-mode bandpass filter of claim 1, wherein each multi-directional vibrating microelectromechanical systems resonator resonates at three resonant frequencies.

9. The multi-mode bandpass filter of claim 1, wherein each multi-directional vibrating microelectromechanical systems resonator has a resonator width, a resonator length and a resonator thickness.

10. The multi-mode bandpass filter of claim 9, wherein each resonator width, resonator length and resonator thickness of each multi-directional vibrating microelectromechanical systems resonator is associated with a resonant frequency.

11. The multi-mode bandpass filter of claim 1, wherein each multi-directional vibrating microelectromechanical systems resonator has a resonator width and a corresponding first transverse piezoelectric coefficient, a resonator length and a corresponding second transverse piezoelectric coefficient and a resonator thickness and a corresponding longitudinal piezoelectric coefficient.

12. The multi-mode bandpass filter of claim 11, wherein each resonator width and corresponding first transverse piezoelectric coefficient, resonator length and corresponding second transverse piezoelectric coefficient and resonator thickness and corresponding longitudinal piezoelectric coefficient of each multi-directional vibrating microelectromechanical systems resonator is associated with a resonant frequency.

13. The multi-mode bandpass filter of claim 1, wherein the first multi-directional vibrating microelectromechanical systems resonator comprises a first resonator width, a first resonator thickness and a first resonator length, and wherein the second multi-directional vibrating microelectromechanical systems resonator comprises a second resonator width, a second resonator thickness and a second resonator length.

14. The multi-mode bandpass filter of claim 13, wherein each of the first resonator width, the first resonator thickness, the first resonator length, the second resonator width, the second resonator thickness and the second resonator length is associated with a resonant frequency.

15. The multi-mode bandpass filter of claim 14, wherein each of the resonant frequencies associated with the first resonator width, the first resonator thickness and the first resonator length are offset from each of the resonant frequencies associated with the second resonator width, the second resonator thickness and the second resonator length.

16. The multi-mode bandpass filter of claim 15, wherein a frequency range of the offset for each of the resonant frequencies corresponds to a bandwidth of frequencies passed by the multi-mode bandpass filter.

17. The multi-mode bandpass filter of claim 14, wherein each of the resonant frequencies associated with the first resonator width, the first resonator thickness and the first resonator length are aligned with each of the resonant frequencies associated with the second resonator width, the second resonator thickness and the second resonator length.

18. The multi-mode bandpass filter of claim 17, wherein a bandwidth of frequencies passed by the multi-mode bandpass filter corresponds to a first electromechanical coupling of the first multi-directional vibrating microelectromechanical systems resonator and a second electromechanical coupling of the second multi-directional vibrating microelectromechanical systems resonator.

19. A method for generating a multi-mode bandpass filter, comprising:
generating a parallel multi-directional vibrating microelectromechanical systems resonator;
generating a series multi-directional vibrating microelectromechanical systems resonator; and
generating a multi-mode bandpass filter using the parallel multi-directional vibrating microelectromechanical systems resonator and the series multi-directional vibrating microelectromechanical systems resonator.

20. The method of claim 19, further comprising:
determining a desired resonator width, resonator length and resonator thickness of the parallel multi-directional vibrating microelectromechanical systems resonator; and
determining a desired resonator width, resonator length and resonator thickness of the series multi-directional vibrating microelectromechanical systems resonator.

21. The method of claim 20, wherein the parallel multi-directional vibrating microelectromechanical systems resonator is generated with the desired resonator width, resonator length and resonator thickness of the parallel multi-directional vibrating microelectromechanical systems resonator, and wherein the series multi-directional vibrating microelectromechanical systems resonator is generated with the desired resonator width, resonator length and resonator thickness of the series multi-directional vibrating microelectromechanical systems resonator.

22. The method of claim 19, wherein each of the multi-directional vibrating microelectromechanical systems resonator comprises:
a piezoelectric material;
a first electrode on a first surface of the piezoelectric material; and
a second electrode on a second surface of the piezoelectric material.

23. The method of claim 22, wherein an electric field applied across the first electrode and the second electrode induces mechanical deformation in at least one plane of the piezoelectric material.

24. The method of claim 22, wherein the piezoelectric material comprises one of aluminum nitride, lithium niobate, lithium tantalate, lead zirconate titanate, zinc oxide and quartz.

25. The method of claim 22, wherein the first electrode is an input electrode, and wherein the second electrode is an output electrode.

26. The method of claim 22, wherein each multi-directional vibrating microelectromechanical systems resonator has a first transverse piezoelectric coefficient, second transverse piezoelectric coefficient and a longitudinal piezoelectric coefficient for the piezoelectric material.

27. The method of claim 26, wherein each first transverse piezoelectric coefficient, second transverse piezoelectric coefficient and longitudinal piezoelectric coefficient of each multi-directional vibrating microelectromechanical systems resonator is associated with a resonant frequency.

28. The method of claim 19, wherein each multi-directional vibrating microelectromechanical systems resonator resonates at three resonant frequencies.

29. The method of claim 19, wherein each multi-directional vibrating microelectromechanical systems resonator has a resonator width, a resonator length and a resonator thickness.

30. The method of claim 29, wherein each resonator width, resonator length and resonator thickness of each multi-directional vibrating microelectromechanical systems resonator is associated with a resonant frequency.

31. The method of claim 19, wherein each multi-directional vibrating microelectromechanical systems resonator has a resonator width and a corresponding first transverse piezoelectric coefficient, a resonator length and a corresponding second transverse piezoelectric coefficient and a resonator thickness and a corresponding longitudinal piezoelectric coefficient.

32. The method of claim 31, wherein each resonator width and corresponding first transverse piezoelectric coefficient, resonator length and corresponding second transverse piezoelectric coefficient and resonator thickness and corresponding longitudinal piezoelectric coefficient of each multi-directional vibrating microelectromechanical systems resonator is associated with a resonant frequency.

33. The method of claim 19, wherein the parallel multi-directional vibrating microelectromechanical systems resonator comprises a first resonator width, a first resonator thickness and a first resonator length, and wherein the series multi-directional vibrating microelectromechanical systems resonator comprises a second resonator width, a second resonator thickness and a second resonator length.

34. The method of claim 33, wherein each of the first resonator width, the first resonator thickness, the first resonator length, the second resonator width, the second resonator thickness and the second resonator length is associated with a resonant frequency.

35. The method of claim 34, wherein each of the resonant frequencies associated with the first resonator width, the first resonator thickness and the first resonator length are offset from each of the resonant frequencies associated with the second resonator width, the second resonator thickness and the second resonator length.

36. The method of claim 35, wherein a frequency range of the offset for each of the resonant frequencies corresponds to a bandwidth of frequencies passed by the multi-mode bandpass filter.

37. The method of claim 34, wherein each of the resonant frequencies associated with the first resonator width, the first resonator thickness and the first resonator length are aligned with each of the resonant frequencies associated with the second resonator width, the second resonator thickness and the second resonator length.

38. The method of claim 37, wherein a bandwidth of frequencies passed by the multi-mode bandpass filter corresponds to a first electromechanical coupling of the parallel multi-directional vibrating microelectromechanical systems resonator and a second electromechanical coupling of the series multi-directional vibrating microelectromechanical systems resonator.

39. An apparatus configured for generating a multi-mode bandpass filter, comprising:
means for generating a parallel multi-directional vibrating microelectromechanical systems resonator;
means for generating a series multi-directional vibrating microelectromechanical systems resonator; and
means for generating a multi-mode bandpass filter using the parallel multi-directional vibrating microelectromechanical systems resonator and the series multi-directional vibrating microelectromechanical systems resonator.

40. The apparatus of claim 39, wherein each of the multi-directional vibrating microelectromechanical systems resonator comprises:
a piezoelectric material;
a first electrode on a first surface of the piezoelectric material; and
a second electrode on a second surface of the piezoelectric material.

41. The apparatus of claim 39, wherein each multi-directional vibrating microelectromechanical systems resonator resonates at three resonant frequencies.

42. A computer-program product for generating a multi-mode bandpass filter, the computer-program product comprising a non-transitory computer-readable medium having instructions thereon, the instructions comprising:
code for causing an apparatus to generate a parallel multi-directional vibrating microelectromechanical systems resonator;
code for causing the apparatus to generate a series multi-directional vibrating microelectromechanical systems resonator; and
code for causing the apparatus to generate a multi-mode bandpass filter using the parallel multi-directional vibrating microelectromechanical systems resonator and the series multi-directional vibrating microelectromechanical systems resonator.

43. The computer-program product of claim 42, wherein each of the multi-directional vibrating microelectromechanical systems resonator comprises:
a piezoelectric material;
a first electrode on a first surface of the piezoelectric material; and
a second electrode on a second surface of the piezoelectric material.

44. The computer-program product of claim 42, wherein each multi-directional vibrating microelectromechanical systems resonator resonates at three resonant frequencies.

45. A multi-band microelectromechanical systems filter, comprising:
a piezoelectric material;
a first electrode on a first surface of the piezoelectric material;
a second electrode on the first surface of the piezoelectric material; and
a third electrode on a second surface of the piezoelectric material, wherein an electric field applied across the piezoelectric material induces mechanical deformation in at least one plane of the piezoelectric material.

46. The multi-band microelectromechanical systems filter of claim 45, wherein the first electrode is a first port electrode, wherein the second electrode is a second port electrode, and wherein the third electrode is a ground electrode.

47. The multi-band microelectromechanical systems filter of claim 45, wherein the first electrode is an antenna electrode, wherein the second electrode is a receiver electrode, wherein the third electrode is a ground electrode, and wherein the multi-band microelectromechanical systems filter further comprises a transmitter electrode on the second surface of the piezoelectric material.

48. The multi-band microelectromechanical systems filter of claim 45, wherein the first electrode is a first antenna electrode, wherein the second electrode is a second antenna electrode, wherein the third electrode is a first ground electrode, and wherein the multi-band microelectromechanical systems filter further comprises:
a positive receiver electrode and a positive transmitter electrode on the first surface of the piezoelectric material; and
a second ground electrode, a negative receiver electrode and a negative transmitter electrode on the second surface of the piezoelectric material.

49. The multi-band microelectromechanical systems filter of claim 45, wherein the first electrode is a first antenna electrode, wherein the second electrode is a receiver electrode, wherein the third electrode is a second antenna electrode, and wherein the multi-band microelectromechanical systems filter further comprises a transmitter electrode on the second surface of the piezoelectric material, wherein the first antenna electrode and the receiver electrode are perpendicular to the second antenna electrode and the transmitter electrode.

50. The multi-band microelectromechanical systems filter of claim 45, wherein the first electrode is a first antenna electrode, wherein the second electrode is a positive transmitter electrode, wherein the third electrode is a ground electrode, and wherein the multi-band microelectromechanical systems filter further comprises a second antenna electrode and a positive receiver electrode on the first surface of the piezoelectric material.

51. The multi-band microelectromechanical systems filter of claim 45, wherein the first electrode is an antenna electrode, wherein the third electrode is a first band electrode, wherein the second electrode is a second band electrode, and wherein the multi-band microelectromechanical systems filter further comprises a control electrode on the second surface of the piezoelectric material, wherein properties of an electric field passing between the control electrode and the second band electrode are changed when a control signal is applied to the control electrode.
